(19) United States
(12) Patent Application Publication
(10) Pub. No.: US 2023/0124794 A1
(43) Pub. Date: Apr. 20, 2023

(54) MICRO-LED WITH REFLECTANCE REDISTRIBUTION

(71) Applicant: Lumileds LLC, San Jose, CA (US)

(72) Inventors: Nicola Bettina Pfeffer, Eindhoven (NL); Arjen Gerben Van der Sijde, Eindhoven (NL); Antonio Lopez Julia, Vaals (NL)

(21) Appl. No.: 17/964,463

(22) Filed: Oct. 12, 2022

Related U.S. Application Data
(60) Provisional application No. 63/255,574, filed on Oct. 14, 2021.

(51) Int. Cl. H01L 33/54; H01L 33/20; H01L 33/32; H01L 33/46

(52) U.S. Cl. CPC H01L 33/54; H01L 33/20; H01L 33/32; H01L 33/46; H01L 2933/005; H01L 2933/0025; H01L 2933/0091

(57) ABSTRACT

A structure and method of micro-LEDs are described. The micro-LEDs have a GaN semiconductor structure containing a multi-quantum well active region configured to emit light of a visible wavelength range and a structure to increase specular reflection of ambient light by proving scattering at one or more interfaces of the micro-LEDs. The interfaces include the air-encapsulant interface, semiconductor-encapsulant interface, or semiconductor-contact interface.

### PRIORITY CLAIM

This application claims the benefit of priority to U.S. Provisional Pat. Application Serial No. 63/255,574, filed Oct. 14, 2021, which is incorporated herein by reference in its entirety.

### TECHNICAL FIELD

The present disclosure relates generally to light-emitting diodes (LEDs) and LED arrays, and, more specifically, to modifying reflections within a micro-LED.

### BACKGROUND

The field of micro-light-emitting diode (micro-LED) arrays is an emerging technology in lighting and display industries. Micro-LED arrays often include thousands to millions of microscopic light-emitting diode (LED) pixels that can emit light and that can be individually controlled or controlled in groups of pixels (e.g., 5×5 groups of pixels). Micro-LED arrays may provide higher brightness and better energy efficiency than other lighting technologies and display technologies, which can make the micro-LED arrays desirable for multiple different applications, such as televisions, automotive headlamps, and mobile phones, among others.

### BRIEF DESCRIPTION OF THE DRAWINGS

To provide a more complete understanding and features and advantages thereof, reference is made to the following description, taken in conjunction with the accompanying figures, wherein like reference numerals represent like parts, in which:

FIG. 1 illustrates a top view of a microLED display, according to some embodiments.

FIG. 2A illustrates a simplified cross-sectional view of a unit cell of a microLED display, according to some embodiments.

FIG. 2B illustrates a simplified cross-sectional view of another microLED display structure, according to some embodiments.

FIG. 3A illustrates a cross-sectional view of a microLED structure, according to some embodiments.

FIG. 3B illustrates a cross-sectional view of another microLED structure, according to some embodiments.

FIG. 3C illustrates a cross-sectional view of a semiconductor structure, according to some embodiments.

FIG. 3D illustrates another cross-sectional view of a semiconductor structure, according to some embodiments.

FIG. 4A illustrates ambient light reflectance for the structure shown in FIG. 2B, according to some embodiments.

FIG. 4B illustrates extraction efficiency for the structure shown in FIG. 2B, according to some embodiments.

FIG. 5 illustrates an example system, according to some embodiments.

FIG. 6 illustrates an example lighting system, according to some embodiments.

FIG. 7 illustrates an example hardware arrangement for implementing the lighting system, according to some embodiments.

FIG. 8 illustrates an example hardware arrangement for implementing the systems herein, according to some embodiments.

FIG. 9 shows a block diagram of an example of a visualization system, according to some embodiments.

FIG. 10 illustrates an example method of fabricating a micro-LED array, according to some embodiments.

### DETAILED DESCRIPTION

The systems, methods, and devices of this disclosure may include one or more innovative aspects, where the innovative aspects may individually or in combination contribute to the desirable attributes disclosed herein. Details of one or more implementations of the subject matter described in this specification are set forth in the description below and the accompanying drawings.

As above, microLEDs are small (e.g., < 0.01 mm), typically red, green, and blue inorganic LEDs arranged in a matrix. The inorganic material (e.g., InGaAsP, AlGaAs, etc...) is more robust than the organic LEDs. In addition, the microLEDs allow direct emission and can be more efficient than the conventional combination of backlight and liquid crystal display (LCD).

One challenge in directly emissive displays is the reduction in contrast due to ambient lighting. Where polarizers in a path that includes the backlight and LCD can reduce unwanted reflection from the ambient (daylight) lighting in conventional displays, the emissive display can be about twice as efficient if no polarizers are used (as the LED light is not polarized).

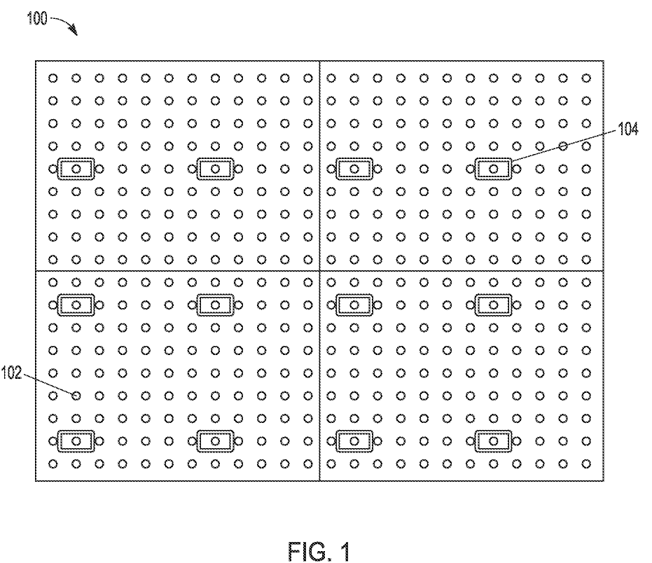

For a microdisplay, the area populated with LEDs is relatively small and the backplane can be optically absorbing (e.g., black), reducing the ambient reflectance significantly as well. With higher density displays however, the microLEDs can occupy 5% of the total area and — being designed for high output -have a highly reflecting backside. This is shown in FIG. 1, which illustrates a top view of a microLED display, according to some embodiments The microLED display 100 contains multiple small squares that include highly reflecting microLEDs 102. The rectangular features are black coated ICs 104 used to drive the microLEDs 102.

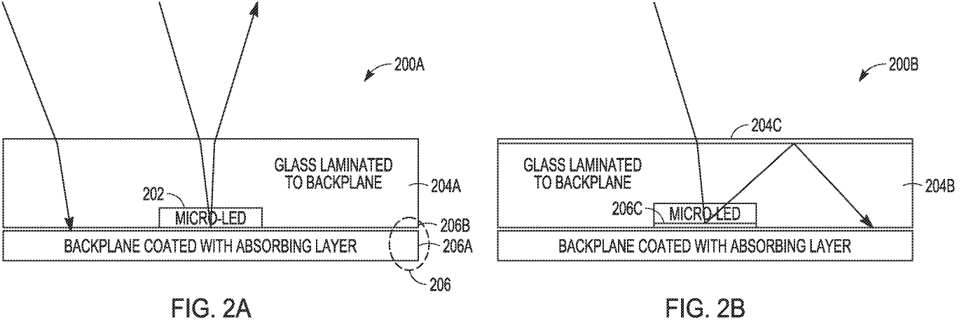

FIG. 2A illustrates a simplified cross-sectional view of a unit cell of a microLED display, according to some embodiments. The microLED structure 200a shown in FIG. 2A includes a microLED 202 disposed on a backplane 206, both of which are covered in an optically-transparent medium 204a. The optically-transparent medium 204a may be, for example, a tough material, like “gorilla glass” that is laminated to the backplane on which driver-controller ICs and microLEDs are mounted to and the traces are laid out. The optically-transparent medium 204a is laminated to reduce dielectrical interfaces and their reflections. The backplane 206 may be coated optically absorbing material, such as dark chromium, in areas other than where used to contact the microLED 202. The microLED 202 may be formed from semiconductor layers doped GaN or a ternary or quaternary semiconductor compound such as InGaN/AlInGaN/AlGaN to permit the microLED 202 to emit light of a desired visible wavelength (e.g., red, green, blue). The microLED 202 may have an active region that, in some embodiments, are formed from one or more quantum wells. The size and material forming the layers of the microLED 202, including the active region determine the wavelength of the light to be emitted from the microLED 202. The entire microLED 202 may range from about 4 µm -about 10 µm, for example. Although not shown, one or more oxide layers (e.g., about 0.5 µm -about 2.0 µm SiO₂) may be formed in the or at the sides of the structure forming the microLED 202, for example. Similarly, side and bottom metal contact layers formed from, e.g., Cu and other materials may provide efficient conductive contact to the anode and cathode of the microLED 202.

After fabricating the microLED 202, the microLED 202 may be attached to the backplane 206. The backplane 206 may be formed from a glass or other supporting structure 206a coated with an absorbing top layer 206b. The absorbing top layer 206b is formed from a material, such as TiW or dark chromium, that is configured to substantially absorb light of at least visible wavelengths. As shown, the absorbing top layer 206b is able to substantially absorb ambient light (and in particular, light of visible wavelengths (about 400 nm - about 800 nm)) that enters the optically-transparent medium 204a and impinges thereon.

The optically-transparent medium 204a is then deposited or otherwise formed on the structure that includes the microLED 202 and the backplane 206. The light is emitted from an emission surface of the microLED 202 through the optically-transparent medium 204a. The optically-transparent medium 204a may be optically-transparent to light of at least visible wavelengths. The optically-transparent medium 204a may be glass, for example, and may be laminated on the backplane 206. The majority of ambient light that enters the optically-transparent medium 204a from the top surface of the optically-transparent medium 204a is absorbed by the backplane 206. However, as shown in FIG. 2A ambient light hitting the microLED 202 is specularly reflected back towards the top surface of the optically-transparent medium 204a, exiting the optically-transparent medium 204a and degrading the performance of the microLED 202 display/application, in particular the contrast of the display.

FIG. 2B illustrates a simplified cross-sectional view of a microLED structure in application, according to some embodiments. As shown in FIG. 2B, ambient light that enters the optically-transparent medium 204b from the top surface of the optically-transparent medium 204b and impinges on the microLED 202 is again reflected back towards the top of the optically-transparent medium 204b. However, in this case, the microLED 202 is modified to alter the light path to increase total internal reflection (TIR) of the ambient light reflected by the microLED 202 and reflect the ambient light back towards the backplane 206, where the ambient light may be absorbed and thus reduce the reflection caused by the microLED 202. An engineered surface 206c with specific characteristics may be provided below the microLED 202. The engineered surface 206c may be, for example, a reflectance layer or a single or multi-layer structure that contains geometric shapes, such as prisms or spheres of one or more sizes, that are configured to alter the reflectance of impinging ambient light within a predetermined range of angles from normal (e.g., up to about 5-10 degrees) to increase the TIR. In other embodiments, the engineered surface layer 206c may be disposed on the top surface of the microLED 202 (more proximate to the optically-transparent medium 204b than the bottom surface of the microLED 202 shown in FIG. 2B) in addition to or instead of being disposed on the bottom surface of the microLED 202.

Similarly, in other embodiments, the external surface 204c of the optically-transparent medium 204b may have similar embedded geometric shapes (e.g., spherical) as the engineered surface 206c in addition to or instead of providing the engineered surface 206c. In other embodiments, electrochemical etching or other patterning may also be used to roughen the external surface 204c of the optically-transparent medium 204b. The external surface 204c of the optically-transparent medium 204b may also be roughened using mechanical means to provide periodic, corrugated, or random structures. The structuring may also be of varying intensity with, for example, stronger structures above the microLED 202 and less further off axis relative to the microLED 202. As an alternative, or in addition, another ‘embedded surface’ could be structured to include a focusing/defocusing design.

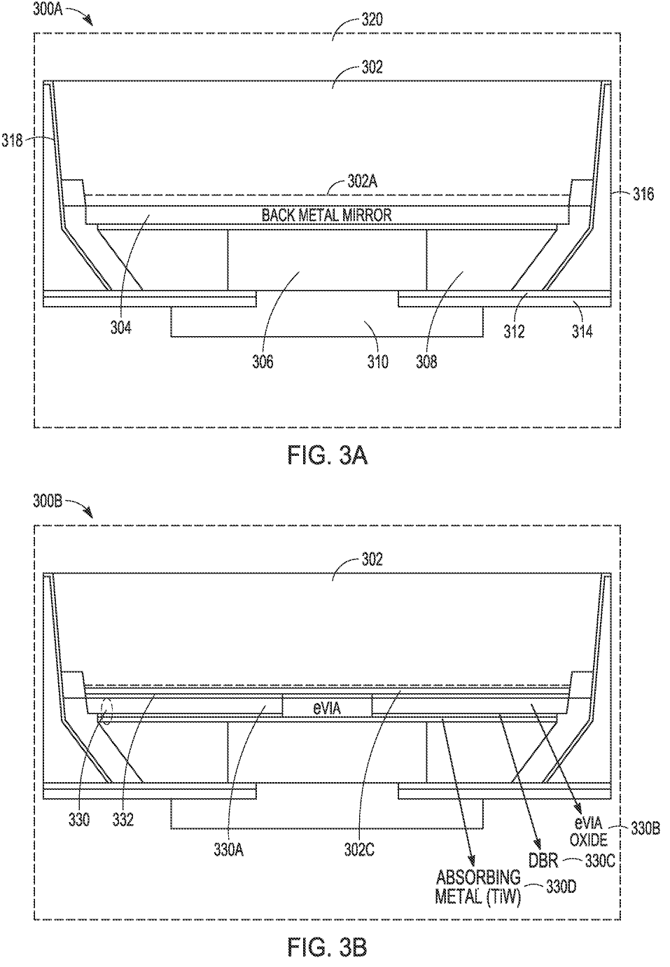

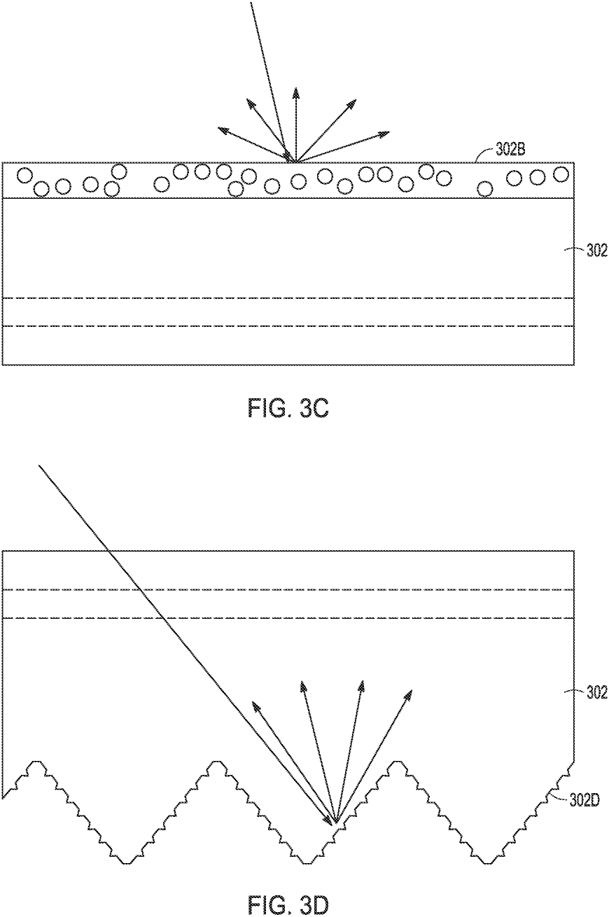

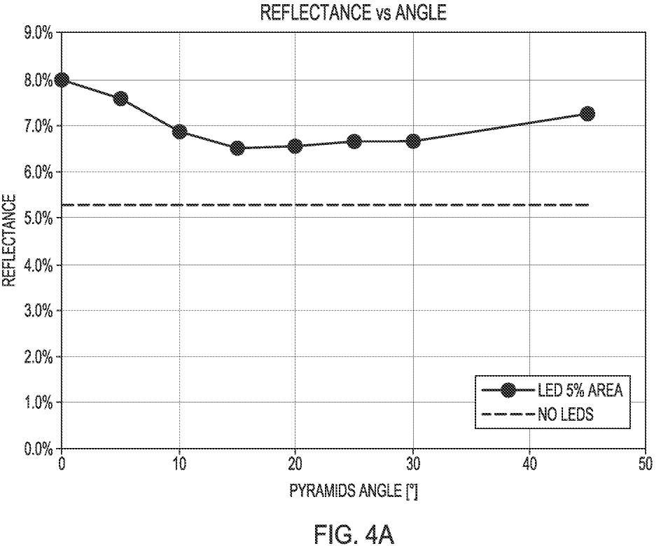

In more detail, FIG. 3A illustrates a cross-sectional schematic view of a microLED structure, according to some embodiments. FIG. 3B illustrates a cross-sectional schematic view of another microLED structure, according to some embodiments. The microLED structure 300a shown in FIG. 3A contains a multilayer semiconductor stack 302 surrounded laterally by a side dielectric layer 316, such as SiO₂, and side metal contact layer 318 and covered with an encapsulant 320 (described in relation to FIGS. 2A and 2B as the optically-transparent medium 204a, 204b). In particular, the microLED 202 shown in FIGS. 2A and 2B may be subdivided in FIGS. 3A and 3B, and the subdivided structure later soldered or wirebonded to the backplane and immersed under the encapsulant 320.

The encapsulant 320 may be formed from, for example, silicone, epoxy or glass or another material that is substantially transparent to at least visible wavelength of light. In some embodiments, the side dielectric layer 316 may be formed from a non-oxide based dielectric material. The multilayer semiconductor stack 302 may be formed using compound semiconductor layers. The thickness of the multilayer semiconductor stack 302 from a top surface of the multilayer semiconductor stack 302 (the emission surface of the microLED structure 300a) may range from about 4 µm - about 10 µm, for example. The semiconductor layers may be formed from doped GaN or a ternary or quaternary semiconductor compound such as InGaN/AlInGaN/AlGaN to permit the multilayer semiconductor stack 302 to emit light of a desired visible wavelength (e.g., red, green, blue). In particular, in some embodiments the multilayer semiconductor stack 302 may have an active region 302a formed from one or more quantum wells. The sizes and materials forming the quantum well(s) determine the wavelength of the light to be emitted from the multilayer semiconductor stack 302.

The side dielectric layer 316 may be formed from SiO₂, for example, and may range from about 0.5 µm - about 2.0 µm or more. As indicated, the thickness of the side dielectric layer 316, as shown, may vary with increasing depth from the top surface of the multilayer semiconductor stack 302. Also as shown, the side metal contact layer 318 is formed along the surface of the side dielectric layer 316. The side metal contact layer 318 may be in contact with an n region of the multilayer semiconductor stack 302 (e.g., GaN). As shown, the side metal contact layer 318 may be exposed at a top surface (adjacent to the top surface of the multilayer semiconductor stack 302) and used to provide a voltage only to a top of the active region 302a. Thus, as shown, the side metal contact layer 318 may contact only the top portion of the multilayer semiconductor stack 302 and is separated from the active region 302a and a lower portion of the multilayer semiconductor stack 302 by an insulator. The side metal contact layer 318 may be formed, e.g., from a Cu layer with thin layer of Al that contacts sidewalls of the multilayer semiconductor stack 302.

The bottom portion of the multilayer semiconductor stack 302 is covered by a back metal mirror 304 The back metal mirror 304 reflects light, whether generated by the microLED or ambient light impinging on the microLED. The back metal mirror 304 also provides electrical contact to the bottom portion of the multilayer semiconductor stack 302 and thus active region 302a. The back metal mirror 304 may be, for example, less than about 1 µm in thickness.

The bottom surface of the back metal mirror 304 may be covered with a backside dielectric layer 308 of, for example, SiO₂. The backside dielectric layer 308 may have a thickness of about 1 µm - about 2 µm, for example. The center of the backside dielectric layer 308 may have a via formed therein in which a metal contact layer 306 is disposed. The metal contact layer 306 may be formed, for example, from Cu and contact the back metal mirror 304 to provide electrical contact to the bottom portion of the multilayer semiconductor stack 302. In some embodiments, the backside dielectric layer 308 may be formed from a non-oxide based dielectric material.

A passivation layer 312 is formed on the bottom surface of the backside dielectric layer 308, as well as on the bottom of the side dielectric layer 316 and the side metal contact layer 318, which extend to the same plane. The passivation layer 312 may be formed from SiN or a similar material. The passivation layer 312 may be about 300 nm - about 500 nm. A bonding layer 314 of 600 nm - about 700 nm is formed on the bottom surface of the passivation layer 312. A via is formed in a center of the passivation layer 312 and the bonding layer 314 to allow electrical contact to the bottom surface of the metal contact layer 306 by a contact layer 310 disposed in the via.

Similar to FIG. 3A, the microLED structure 300b shown in FIG. 3B contains a multilayer semiconductor stack 302 that contains an active region 302a and is surrounded laterally by a side dielectric layer 316 and side metal contact layer 318, a backside dielectric layer 308, a metal contact layer 306, a passivation layer 312, a bonding layer 314, and a contact layer 310. However, the back metal mirror 304 is not present in the embodiment shown in FIG. 3B. Instead, a multilayer reflective structure 330 is disposed on a bottom surface of the multilayer semiconductor stack 302, with an intervening transparent conductive film 332 at the interface between the multilayer semiconductor stack 302 and the multilayer reflective structure 330. The transparent conductive film 332 may be indium tin oxide (ITO), for example. The transparent conductive film 332 permits current applied to one portion of the microLED structure 300b to spread laterally into the remainder of the pixel area

The multilayer reflective structure 330 includes an eVia oxide layer 330b in which an eVia 330a is formed to provide electrical contact to the multilayer semiconductor stack 302. The eVia oxide layer 330b is essentially transparent to at least visible wavelengths, including the wavelength range emitted by the active region 302a. In other embodiments, materials other than an oxide may be used as long as such materials are essentially transparent to the visible wavelengths. The eVia 330a may be formed from Cu and plated with a contact layer such as AgTiW to contact the p doped region of the multilayer semiconductor stack 302 (e.g., GaN). Although not shown, a thin (e.g., about 20 nm) ITO layer may be disposed between the multilayer semiconductor stack 302 and oxide layer 330b. The ITO layer may be deposited on p-GaN a Ti/Al may then be deposited to provide contact. The oxide layer 330b may have a thickness of about 0.5 µm.

At a bottom surface of the eVia oxide layer 330b, a distributed Bragg reflector (DBR) structure 330c is disposed. The DBR structure 330c may be, for example, a narrowband filter that reflects light within a narrow wavelength range (typically having a bandwidth of about, for example, 170 nm) and transmits the remaining light. In this case, the wavelength range reflected by the DBR structure 330c may be substantially centered around light emitted by the multilayer semiconductor stack 302 (which typically has a bandwidth of about 10 nm - about 50 nm). In other embodiments, the DBR structure is selected as a dielectric mirror to create a mirror on top of a structured surface. The dielectric mirror has the advantage of not reducing the efficiency of the microLED (which a structured metal mirror might result in). In this case, the DBR structure 330c may not be formed as a narrowband filter. The DBR structure 330c has a thickness of about 0.5 µm - about 1 µm. Although a DBR structure 330c is indicated, other Bragg reflectors or other narrowband reflectors may be used that have a relatively high degree of reflectivity at the wavelength range emitted by the active region 302a and significantly less reflectivity at visible wavelength ranges substantially outside the wavelength range emitted by the active region 302a and being highly reflective even if deposited on 3D engineered surfaces.

An absorbing metal 330d is disposed on a lower surface of the DBR structure 330c The absorbing metal 330d may be TiW, or other material that absorbs visible wavelengths at least outside the wavelength range reflected by the DBR structure 330c (and in some embodiments also within the wavelength range reflected by the DBR structure 330c). The absorbing metal 330d have a thickness of about 100 nm, for example. In other embodiments, materials other than a metal may be used to absorb visible wavelengths.

A microLED that contains the microLED structure 300b may as above emit light in a wavelength range defined by the active region 302a. Similarly, the DBR structure 330c of the microLED structure 300b is tailored for high reflectance, preferably to a desired wavelength range to be emitted. MicroLEDs are typically fabricated on a substrate and generally have the same or similar emission characteristics. A microLED array may be used in a variety of devices, such as displays in mobile or other electronic devices, augmented or virtual reality devices, and other devices that use multicolor displays As indicated, an extremely large number (hundreds of thousands to millions) of microLEDs with different emission characteristics may be used in the microLED array to form a single display. The emission characteristics may be perceptible as wholly different colors (e.g., red or blue) and within a perceptible color (e.g., red emitted at about 620 nm, 650 nm, 680 nm, etc...). The variation across colors and within each color may enable desired display characteristics of the overall display containing the microLED array. Accordingly, the microLED array contains microLEDs from multiple different substrates and that have different active regions 302a and DBR structures 330c that are arranged as desired to form the overall display.

In some embodiments, one or more anti-reflecting coatings may be applied to the microLED structure 300b shown in FIG. 3B. The anti-reflecting coating may be applied at one or more interfaces in FIG. 3B. In particular, the anti-reflecting coating may be deposited on a top surface of the encapsulant 320 — e.g., at an interface between air and the encapsulant 320 above the multilayer semiconductor stack 302, on a top surface of the multilayer semiconductor stack 302 — e.g., at an interface between the encapsulant 320 and the multilayer semiconductor stack 302 (one of the doped epitaxial semiconductor layers of the multilayer semiconductor stack 302 opposing the encapsulant 320), and/or at the interface between the transparent conductive film 332 and the eVia oxide layer 330b (or, if another layer is present between the encapsulant 320 and air, such as a glass layer, between the encapsulant 320 and this glass layer). This use of an anti-reflecting coating at one or more of the interfaces described above may reduce or eliminate Fresnel reflections, and thus improve LED emission performance.

Various structures may be used to modify the spectral reflectance of the microLED structure 300a, 300b (although such structures are only shown and described in reference to FIG. 3B). Spectral here is not interpreted as ‘spectrally selective’. Such structures may, in general, be formed at one or more interfaces. In addition to the structures described at the external surface 204c of the optically-transparent medium 204b or encapsulant 320, these structures include, for example, one or more of: nanoparticles disposed on a sapphire substrate or embedded in an etched surface of the sapphire substrate (if the sapphire substrate is present) or in or on the GaN surface (if the sapphire substrate is not present), a multilayer nanoporous structure embedded in the semiconductor structure, and/or GaN surface roughness (e.g., in a thin-film flip-chip structure). The nanoparticles may be self-assembled when disposed on a periodic structure.

In some embodiments, randomly positioned nanospheres (of up to about 100 nm in diameter) may be deposited on a roughened surface 302b of the semiconductor structure to adjust the reflectance in the visible spectrum and provide light scattering, as shown in FIG. 3C For example, for a GaN-based semiconductor structure, silica nanospheres may be deposited on an etched surface of the GaN by spin coating or another deposition or formation process. The refractive indices between the GaN and silica nanospheres create reflectance modulations in which the silica nanospheres act as a reflector in which diffuse reflectance increases with an increase in the number of silica nanospheres. For example, the silica nanospheres may be about 100 nm in diameter, and can be spin-coated on a wet-etched patterned sapphire substrate (e.g., using a H₂SO₄:H₃PO₄ etch) to self-assemble in a periodic fashion on the sapphire substrate, before then growing GaN on the sapphire substrate. Alternatively, nanospheres may be grown in a monolayer, or substantially in a monolayer, on the sapphire substrate and GaN subsequently grown on the monolayer. Either SiO₂ spheres or shells (hollow SiO₂ spheres) may be used. In FIG. 3C, the silica nanospheres are deposited in a monolayer on a surface of the GaN, which may be etched. Although the silica nanospheres are shown as being the same size, the silica nanospheres may have different sizes. Although referred to as spherical, in other embodiments, different shapes (e.g., ovular) may be used in addition to, or instead of spherical.

In some embodiments, an embedded nanoporous structure may be used to increase the scattering. For example, a nanoporous-GaN/undoped-GaN distributed Bragg reflector (DBR) structure 302c may be incorporated into the GaN, e.g., at the bottom of the microLED structure 302. In particular, the n+-GaN layers may have a low refractive index nanoporous GaN structure through a doping-selective electrochemical wet etching process. The DBR structure may be formed, for example, by an AlGaN/GaN stack or an AIN/GaN stack. The embedded voids scatters light effectively. Note that nanoporous refers to media having pores of up to about 100 nm.

In some embodiments, a substrate on which the semiconductor structure is grown may be removed and the exposed layer of the semiconductor structure roughened. For example, for the GaN-based semiconductor structure, the sapphire substrate may be removed using an excimer laser and the exposed GaN (n-doped GaN) photoelectrochemically roughened using a UV lamp and a dilute aqueous solution of potassium hydroxide (KOH). the p-doped GaN may then be metallized and bonded to another semiconductor substrate serving as an anode. The roughened surface 302b increases the diffuse reflectance at the air-semiconductor interface. FIG. 3D illustrates another semiconductor structure, according to some embodiments. Specifically, FIG. 3D shows a roughened GaN surface 302d. The roughening may increase inhomogeneities of the surface to be about 1 µm - about 2 µm in depth. The roughened GaN surface 302d may also be formed by being grown on a patterned sapphire surface.

In some embodiments, a thin AlN layer (e.g., about 20 nm) may be deposited on the Sapphire substrate prior to deposition of SiO₂ features, which increase scattering. The sapphire may be patterned or may be non-patterned prior to deposition of the AlN. For example, a nucleation layer of AlN may be deposited on a non-patterned sapphire substrate using a sputter deposition tool. A SiO₂ layer of about 800 nm may then be coated over the AlN layer using plasma-enhanced chemical vapor deposition (PECVD). A hexagonal pattern of circles having a pitch of about 1000 nm and a circle diameter of about 200 nm may be transferred to a photoresist coating on the SiO₂ layer using nanoimprint lithography. The wafer may then be etched in a reactive ion etching (RIE) tool using conditions that etches SiO₂ efficiently but etches AlN at most slowly. After removal of the photoresist and the wafer cleaned, the result is a hexagonal array of SiO₂ cones. The wafer may then be loaded into a III-nitride MOVPE reactor for epitaxy of LED device layers. Unlike a typical MOVPE growth run, which starts with a low temperature nucleation layer, the MOVPE process in this case starts with a high temperature GaN growth —thereby taking advantage of the large difference in GaN nucleation rates on the predeposited AlN vs. the surfaces of the SiO₂ cone features.

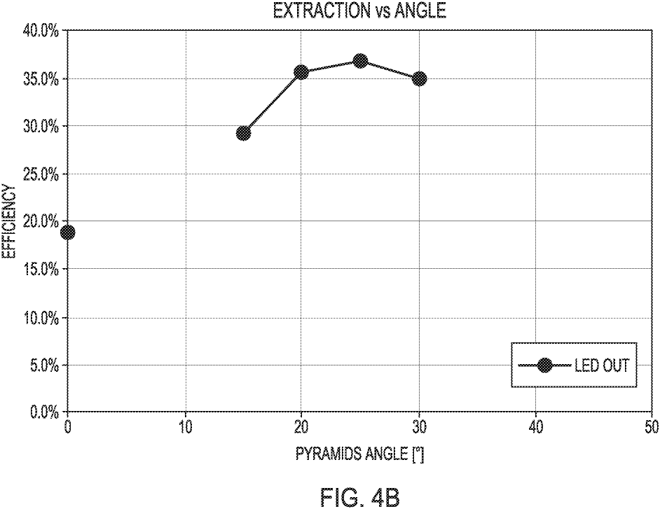

FIG. 4A illustrates ambient light reflectance for the structure shown in FIG. 2B, according to some embodiments. FIG. 4A shows a simulation of reflectance of ambient light as a function of pyramid angle. As can be seen the reflectance is increased by about 3% compared to no LEDs within the display when no measurement is taken and can be reduced by a factor of two with prim angles around 20° to 30° from normal. FIG. 4B illustrates extraction efficiency for the structure shown in FIG. 2B, according to some embodiments. Specifically, as shown in FIG. 4B, the extraction efficiency of LEDs is shown as function of the same prism angle.

As will be appreciated by one skilled in the art, aspects, in particular aspects of micro-LED arrays and control of micro-LED arrays, described herein, may be embodied in various manners — eg., as a method, a system, a computer program product, or a computer-readable storage medium. Accordingly, aspects may take the form of an entirely hardware embodiment, an entirely software embodiment (including firmware, resident software, microcode, etc.) or an embodiment combining software and hardware aspects that may all generally be referred to herein as a “circuit,” “module,” or “system.” Functions described in this disclosure may be implemented as an algorithm executed by one or more hardware processors, e.g., one or more microprocessors, of one or more computers. Although a processor is referred to herein, any logic capable of performing the functions indicated may be used. In various embodiments, different steps and portions of the steps of each of the methods described herein may be performed by different processors. Furthermore, aspects may take the form of a computer program product embodied in one or more computer-readable medium(s), such as a non-transitory medium, having computer-readable program code embodied, e.g., stored, thereon. In various embodiments, such a computer program may, for example, be downloaded (updated) to the existing devices and systems (eg., to the existing lighting systems, etc.) or be stored upon manufacturing of these devices and systems.

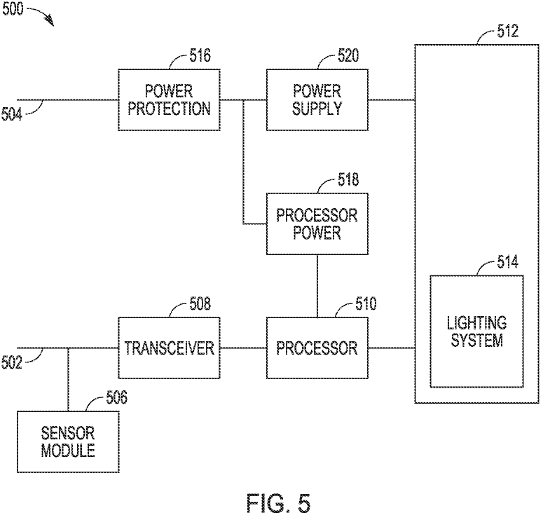

FIG. 5 illustrates an example system 500, according to some embodiments. In some of the embodiments, not all of the components shown in FIG. 5 may be present. The system 500 may be provided in any of the arrangements above, for example, in a luminaire, a mobile device or for indoor or outdoor lighting environs. In some embodiments, the system 500 may also be used in an active headlamp system, or in an augmented reality or a virtual reality device. In any of these applications, the intensity of light and/or an image provided by the light output by the system 500 may be adjusted as described above. The system 500 may implement a pixelated configuration made possible by the micro-LED array.

The system 500 may be coupled to a bus 502 of the apparatus and a power source 504. The power source 504 may provide power for the system 500. The bus 502 may be coupled to one or more components that can provide data and/or utilize data provided to or from the system 500. The data provided on the bus 502 may include, for example, image data of an image to be displayed, user control data (e.g., brightness, contrast adjustments), data related to external system sensors, such as environmental conditions around the system 500 (such as a time of day, whether there is rain, whether there is fog, ambient light levels, and other environmental data), among others. When the system 500 is in a vehicle and the lighting is provided for internal cabin lighting or display, for example, the data provided on the bus 502 may also be related to conditions of the vehicle (such as whether the vehicle is parked, whether the vehicle is in motion, a current speed of the vehicle, a current direction of travel of the vehicle), and/or presence/positions of other vehicles or pedestrians around the vehicle. The system 500 may provide feedback (such as information regarding operation of the system) to the components shown or other components of the device in which the system 500 resides.

The system 500 may further comprise a sensor module 506. In some embodiments, the sensor module 506 may include one or more sensors that can sense surroundings of the system 500. For example, the one or more sensors may sense surroundings that can affect an image to be produced by light emitted by the system 500. In embodiments in which the system 500 is disposed in a vehicle for example, the sensors may sense environmental conditions around the vehicle, and/or presence/positions of other vehicles or pedestrians around the vehicle if not already provided. In other embodiments, such as when the system 500 is disposed in a mobile device, the sensor module 506 may include one or more of an accelerometer, gyroscope, magnetometer, GPS, proximity sensor, ambient light sensor, microphone, touchscreen sensor, among others. The sensor module 506 may operate in combination with the data provided on the bus 502 or may operate in lieu of a portion of the data being provided on the bus 502. The sensor module 506 may output visually (and/or audibly and/or tactilely) data indicating that has been sensed by the sensors.

The system 500 may further include a transceiver 508. The transceiver 508 may have a universal asynchronous receiver-transmitter (UART) interface or a serial peripheral interface (SPI) in some embodiments. The transceiver 508 may also be coupled to the bus 502 and the sensor module 506, and may receive data from the bus 502 and the sensor module 506. In some embodiments, the transceiver 508 may multiplex the data received from the bus 502 and the sensor module 506. The transceiver 508 may direct feedback to the bus 502 or the sensor module 506.

The system 500 may further include a processor 510. The processor 510 may be a hardware processor (single or multiple core) that is coupled to the transceiver 508. The processor 510 may exchange data with the transceiver 508. For example, the processor 510 may receive data from the transceiver 508 that was provided by the bus 502 and/or the sensor module 506. The processor 510 may generate image data that indicates an image to be produced by light emitted from the system 500. The processor 510 may further generate one or more inquiries that request information from one or more of the components (shown or not shown) of the system 500. The processor 510 may further provide the feedback to the transceiver 508 to be directed to the bus 502 and/or the sensor module 506.

The system 500 may further include an illumination device 512. The illumination device 512 may produce multiple different outputs of light. The illumination device 512 may include a lighting system 514 that contains a micro-LED array (which, as above, may be several tens of thousands or more individual micro-LEDs). The illumination device 512 may be coupled to the processor 510 and may exchange data with the processor 510. In particular, the lighting system 514 may be coupled to the processor 510 and may exchange data with the processor 510. The lighting system 514 may receive the image data and inquiries from processor 510 and may provide feedback to the processor 510.

The system 500 may further include power protection 516. The power protection 516 may be coupled to the power source 504 and may receive power from the power source. The power protection 516 may include one or more filters that may reduce conducted emissions and provide power immunity. In some embodiments, the power protection 516 may provide electrostatic discharge (ESD) protection, load-dump protection, alternator field decay protection, reverse polarity protection, or some combination thereof.

The system 500 may further include processor power 518. The processor power 518 may be coupled to the power protection 516 and may receive power from the power source 504. The processor power 518 may comprise, for example, a low-dropout (LDO) regulator that may generate power for powering the processor 510 from the power provided by the power source 504. The processor power 518 may further be coupled to the processor 510 and may provide power to the processor 510.

The system 500 may further comprise a power supply 520. The power supply 520 may be coupled to the power protection 516 and may receive power from the power source 504. In some embodiments, the power supply 520 may comprise a converter that converts the power from the power source 504 to power for the illumination device 512. For example, the power supply 520 may comprise a direct current (DC)-to-DC converter that converts the power from the power supply 520 from a first voltage to a second voltage for the lighting system 514 of the illumination device 512.

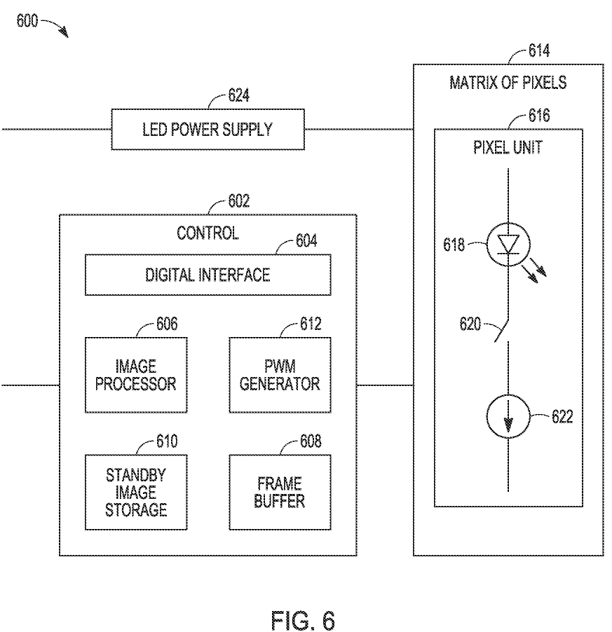

FIG. 6 illustrates an example lighting system 600, according to some embodiments. As above, some of the elements shown in the lighting system 600 may not be present, while other additional elements may be disposed in the lighting system 600. The system 500 shown in FIG. 5 may include one or more of the features of the lighting system 600. The lighting system 600 may include a control module 602. In some embodiments, some or all of the components described as the control module 602 may be disposed on, for example, a compound metal oxide semiconductor (CMOS) backplane. In some embodiments, e.g., larger displays, a glass backplane may be used. In this case, the semiconductor material may be deposited to form the transistors to control the individual pixels. The control module 602 may be coupled to or include the processor 510 of the overall system 500 shown in FIG. 5. The control module 602 may receive image data and inquiries from the processor 510. The control module 602 may further provide feedback to the processor 510.

The control module 602 may include a digital interface 604. The digital interface 604 may facilitate communication with the processor and other components within the lighting system 600. For example, the digital interface 604 may comprise an SPI interface in some embodiments, where the SPI interface may facilitate communication.

The control module 602 may further include an image processor 606. The image processor 606 may be a dedicated processor that is different from, or may be the same as, the processor 510 shown in FIG. 5. The image processor 606 may receive the image data via the digital interface 604 and may process the image data to produce indications of, for example, PWM duty cycles and/or intensities of light for causing the lighting system 600 to produce the images indicated by the image data based on the calibration described above.

The control module 602 may further include a frame buffer 608 and a standby image storage 610. The frame buffer 608 may receive the indications produced by the image processor 606 and store the indications for implementation. The standby image storage 610 may further store indications of PWM duty cycles, intensities of light, and/or turn-on times. The indications stored in the standby image storage 610 may be implemented in the absence of indications stored in the frame buffer 608. For example, the frame buffer 608 may retrieve the indications from the standby image storage 610 when the frame buffer 608 is empty.

The control module 602 may further include a PWM generator 612. The PWM generator 612 may receive the indications from the frame buffer 608 and may produce PWM signals in accordance with the indications. The PWM generator 612 may further determine intensities of light based on the indications and produce a signal to cause the intensities of light to be produced.

The lighting system 600 may include a micro-LED array 614. The micro-LED array 614 may include a plurality of pixels, where each of the pixels includes a pixel unit 616 that may be controlled individually or in groups of pixel units 616. In particular, the pixel unit 616 may include an LED 618, a PWM switch 620, and a current source 622. The pixel unit 616 may receive the signals from the PWM generator 612. The PWM signal from the PWM generator 612 may cause the PWM switch 620 to open and close in accordance with the value of the PWM signal. The signal corresponding to the intensities of light may cause the current source 622 to produce a current flow to cause the LED 618 to produce the corresponding intensities of light.

The lighting system 600 may further include an LED power supply 624. In some embodiments, the LED power supply 624 may be coupled to the power supply 520 and may receive power from the power supply 520. The LED power supply 624 may produce power for the LEDs of the micro-LED array 614. The LED power supply 624 may be coupled to the micro-LED array 614 and may provide the power for the LEDs to the micro-LED array 614.

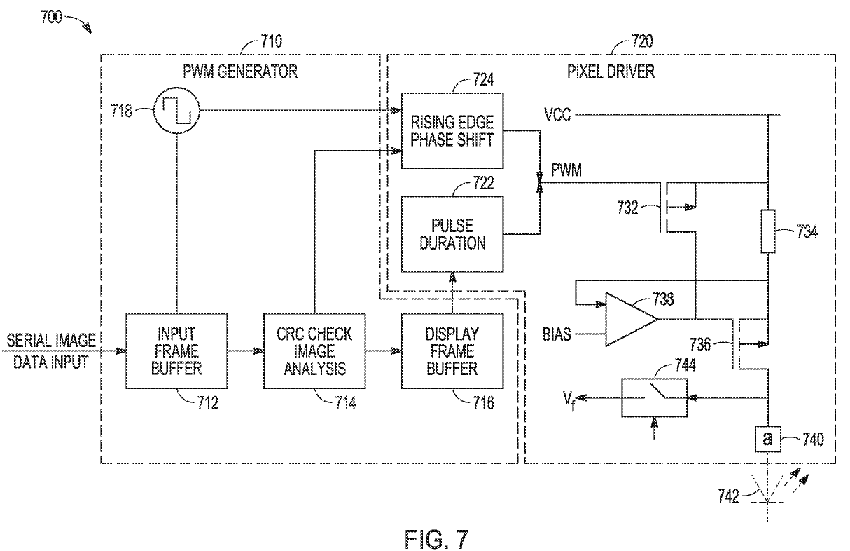

FIG. 7 illustrates an example hardware arrangement for implementing the system, according to some embodiments. As above, only one embodiment of the hardware arrangement is shown; in other embodiments, some of the elements may not be present or other elements may be added. In particular, the hardware arrangement 700 of FIG. 7 shows further specifics of the control module 602 and the micro-LED array 614 of the lighting system 600 as described above. Note that not all elements may be shown, such as the processor and memories used to provide the functionality of the various modules shown in FIG. 7. In some embodiments, the circuitry shown in FIG. 7 may be provided on, for example, a CMOS backplane.

The control module 710 may be supplied with data to control the LEDs 742. In particular, the control module 710 contains an input frame buffer 712 having an input to which serial image data to be provided for display may be received via the digital interface. The serial image data may include indications produced by the image processor (not shown). The input frame buffer 712 may retrieve the indications from the standby image storage when the input frame buffer 712 is empty for use to display. The input frame buffer 712 may provide the serial image data to a cyclic redundancy check (CRC) image analysis module 714 of the processor, which may determine whether the serial image data buffered is valid. If so, the valid data may be supplied to a display frame buffer 716.

Data from the CRC image analysis module 714 and the display frame buffer 716 may be supplied to the pixel driver 720 to drive the LEDs 742. In particular, the data from the CRC image analysis module 714 may be supplied to a rising edge phase shift module 724 of the pixel driver 720 while data from the display frame buffer 716 may be supplied to a pulse duration module 722 of the pixel driver 720. The rising edge phase shift module 724 may also receive a PWM of a predetermined frequency from a PWM generator 718. Thus, the CRC image analysis module 714 data may be used by the rising edge phase shift module 724 to determine how much to shift the rising edge of the PWM signal, while the data from the display frame buffer 716 may be used to adjust the duration of the resulting PWM signal.

The resulting phase-shifted and duration-adjusted PWM signal may be supplied to a control terminal of an input transconductance device 732. As shown the input transconductance device 732 may be a p-channel enhancement type MOSFET, although other types of FETs or other devices may be used. Thus, the altered PWM signal may be supplied to the gate of the MOSFET 732. The source of the MOSFET 732 may be connected with the power supply Vcc. The drain of the MOSFET 732 may be connected with an output of a comparator 738 and with the control terminal of another MOSFET 736. The inputs of the comparator 738 may be a predetermined bias voltage and a voltage that is dependent on the altered PWM signal. The source of the MOSFET 732 (and thus PWM signal) is coupled to one end of a resistor 734 and the other end of the resistor 734 may be coupled to another input of the comparator 738 and the source of the other MOSFET 736. The drain of the other MOSFET 736 may be coupled to an amplifier 740 before being supplied to the LEDs 742. The drain of the other MOSFET 736 may also be coupled to a switch 744 to supply a feedback voltage to the control module 710.

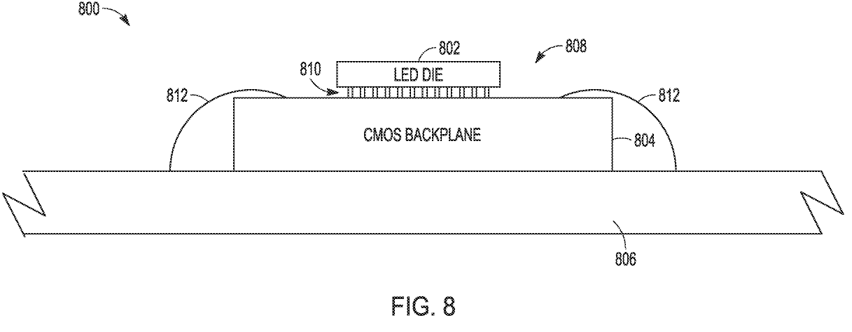

FIG. 8 illustrates an example hardware arrangement 800 for implementing the above disclosed subject matter, according to some embodiments. In particular, the hardware arrangement 800 may illustrate hardware components that may implement the system 500 for a CMOS driver — other arrangements may be used for other types of backplanes such as a TFT backplane or mixed TFT and IC backplane. The hardware arrangement 800 may include an integrated LED 808 The integrated LED 808 may include an LED die 802 and a backplane 804. The LED die 802 may be coupled to the backplane 804 by one or more interconnects 810, where the interconnects 810 may provide for transmission of signals between the LED die 802 and the backplane 804. The interconnects 810 may comprise one or more solder bump joints, one or more copper pillar bump joints, other types of interconnects known in the art, or some combination thereof.

The LED die 802 may include circuitry to implement the micro-LED array. In particular, the LED die 802 may include a plurality of micro-LEDs. The LED die 802 may include a shared active layer and a shared substrate for the micro-LED array, and thereby the micro-LED array may be a monolithic micro-LED array. Each micro-LED of the micro-LED array may include an individual segmented active layer and/or substrate. In some embodiments, the LED die 802 may further include switches and current sources to drive the micro-LED array. In other embodiments, the PWM switches and the current sources may be included in the CMOS backplane 804.

The backplane 804 may include circuitry to implement the control module and/or the LED power supply. The backplane 804 may utilize the interconnects 810 to provide the micro-LED array with the PWM signals and the signals for the intensity for causing the micro-LED array to produce light in accordance with the PWM signals and the intensity. Because of the relatively large number and density of connections to drive the micro-LED array compared to standard LED arrays, different embodiments may be used to electrically connect the backplane 804 and the LED die 802. Either the bonding pad pitch of the backplane 804 may be the same as the pitch of bonding pads in the micro-LED array, or the bonding pad pitch of the backplane 804 may be larger than the pitch of bonding pads in the micro-LED array.

The hardware arrangement 800 may further include a PCB 806. The PCB 806 may include circuitry to implement functionality such as that shown in, for example, FIG. 5 (the power protection 516, the processor power 518, the sensor module 506, the transceiver 508, the processor 510, or portions thereof). The PCB 806 may be coupled to the backplane 804. For example, the PCB 806 may be coupled to the backplane 804 via one or more wire bonds 812. The PCB 806 and the backplane 804 may exchange image data, power, and/or feedback via the coupling, among other signals.

As shown, the micro-LEDs and circuitry supporting the micro-LED array can be packaged and include a submount or printed circuit board for powering and controlling light production by the micro-LEDs. The PCB 806 supporting the micro-LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the micro-LED array and a power supply, and also provide heat sink functionality.

As above, a variety of applications may be supported by micro-LED arrays. Such applications may include a stand-alone applications to provide general illumination (e.g., within a room or vehicle) or to provide specific images. In addition to devices such as a luminaire, projector, mobile device, the system may be used to provide either augmented reality (AR) and virtual reality (VR)-based applications. Various types of devices may be used to provide AR/VR to users, including headsets, glasses, and projectors. Such an AR/VR system may include components similar to those described above, the micro-LED array, a display or screen (which may include touchscreen elements), a micro-LED array controller, sensors, and a controller, among others. The AR/VR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data. Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the AR/VR system relative to an initial position can be determined.

In some embodiments, the controller may control individual micro-LEDs or one or more micro-LED pixels (groups of micro-LEDs) to display content (AR/VR and/or non-AR/VR) to the user while controlling other micro-LEDs and sensors used in eye tracking to adjust the content displayed. Content display micro-LEDs may be designed to emit light within the visible band (approximately 400 nm to 780 nm) while micro-LEDs used for tracking may be designed to emit light in the IR band (approximately 780 nm to 2,200 nm). In some embodiments, the tracking micro-LEDs and content micro-LEDs may be simultaneously active. In some embodiments, the tracking micro-LEDs may be controlled to emit tracking light during a time period that content micro-LEDs are deactivated and are thus not displaying content to the user. The AR/VR system can incorporate optics, such as those described above, and/or an AR/VR display, for example to couple light emitted by micro-LED array onto the AR/VR display.

In some embodiments, the AR/VR controller may use data from the sensors to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow. Based on changes in position, orientation, or movement of the AR/VR system, the system controller can send images or instructions the light emitting array controller. Changes or modification the images or instructions can also be made by user data input, or automated data input.

In general, in a VR system, a display can present to a user a view of scene, such as a three-dimensional scene. The user can move within the scene, such as by repositioning the user’s head or by walking. The VR system can detect the user’s movement and alter the view of the scene to account for the movement. For example, as a user rotates the user’s head, the system can present views of the scene that vary in view directions to match the user’s gaze. In this manner, the VR system can simulate a user’s presence in the three-dimensional scene. Further, a VR system can receive tactile sensory input, such as from wearable position sensors, and can optionally provide tactile feedback to the user.

In an AR system, on the other hand, the display can incorporate elements from the user’s surroundings into the view of the scene. For example, the AR system can add textual captions and/or visual elements to a view of the user’s surroundings. For example, a retailer can use an AR system to show a user what a piece of furniture would look like in a room of the user’s home, by incorporating a visualization of the piece of furniture over a captured image of the user’s surroundings. As the user moves around the user’s room, the visualization accounts for the user’s motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user’s surroundings.

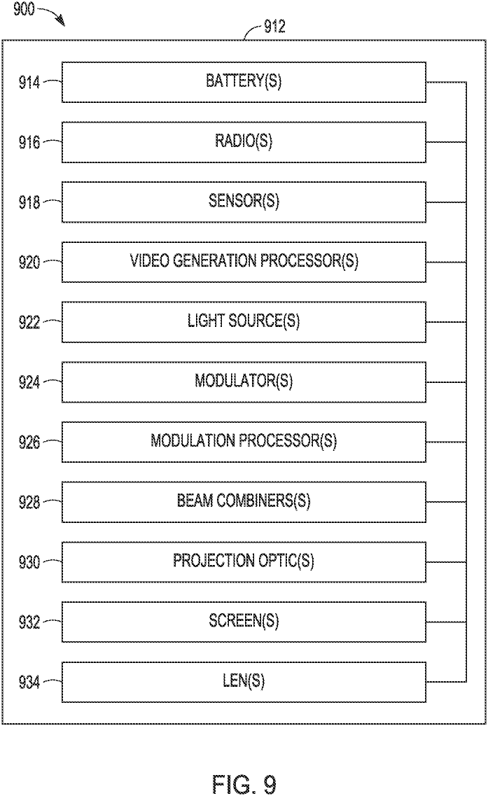

FIG. 9 shows a block diagram of an example of a visualization system, according to some embodiments. The visualization system 910 can include a wearable housing 912, such as a headset or goggles. The housing 912 can mechanically support and house the elements detailed below. In some examples, one or more of the elements detailed below can be included in one or more additional housings that can be separate from the wearable housing 912 and couplable to the wearable housing 912 wirelessly and/or via a wired connection. For example, a separate housing can reduce the weight of wearable goggles, such as by including batteries, radios, and other elements. The housing 912 can include one or more batteries 914, which can electrically power any or all of the elements detailed below. The housing 912 can include circuitry that can electrically couple to an external power supply, such as a wall outlet, to recharge the batteries 914. The housing 912 can include one or more radios 916 to communicate wirelessly with a server or network via a suitable protocol, such as WiFi.

The visualization system 910 can include one or more sensors 918, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 918 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an AR system, one or more of the sensors 918 can capture a real-time video image of the surroundings proximate a user.

The visualization system 910 can include one or more video generation processors 920. The one or more video generation processors 920 can receive scene data that represents a three-dimensional scene, such as a set of position coordinates for objects in the scene or a depth map of the scene. This data may be received from a server and/or a storage medium. The one or more video generation processors 920 can receive one or more sensor signals from the one or more sensors 918. In response to the scene data, which represents the surroundings, and at least one sensor signal, which represents the location and/or orientation of the user with respect to the surroundings, the one or more video generation processors 920 can generate at least one video signal that corresponds to a view of the scene. In some examples, the one or more video generation processors 920 can generate two video signals, one for each eye of the user, that represent a view of the scene from a point of view of the left eye and the right eye of the user, respectively. In some examples, the one or more video generation processors 920 can generate more than two video signals and combine the video signals to provide one video signal for both eyes, two video signals for the two eyes, or other combinations.

The visualization system 910 can include one or more light sources 922 that can provide light for a display of the visualization system 910. Suitable light sources 922 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and has light-emitting diode elements that are individually addressable and controllable (and/or controllable in groups and/or subsets), an array of micro-light-emitting diodes (microLEDs), and others.

A light-emitting diode can be white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, that has a wavelength greater than a wavelength of the excitation light.

The one or more light sources 922 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The visualization system 910 can include one or more modulators 924. The modulators 924 can be implemented in one of at least two configurations.

In a first configuration, the modulators 924 can include circuitry that can modulate the light sources 922 directly. For example, the light sources 922 can include an array of light-emitting diodes, and the modulators 924 can directly modulate the electrical power, electrical voltage, and/or electrical current directed to each light-emitting diode in the array to form modulated light. The modulation can be performed in an analog manner and/or a digital manner. In some examples, the light sources 922 can include an array of red light-emitting diodes, an array of green light-emitting diodes, and an array of blue light-emitting diodes, and the modulators 924 can directly modulate the red light-emitting diodes, the green light-emitting diodes, and the blue light-emitting diodes to form the modulated light to produce a specified image.

In a second configuration, the modulators 924 can include a modulation panel, such as a liquid crystal panel. The light sources 922 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 924 can include multiple modulation panels that can modulate different colors of light. For example, the modulators 924 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 924 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 910 can include one or more modulation processors 926, which can receive a video signal, such as from the one or more video generation processors 920, and, in response, can produce an electrical modulation signal. For configurations in which the modulators 924 directly modulate the light sources 922, the electrical modulation signal can drive the light sources 924. For configurations in which the modulators 924 include a modulation panel, the electrical modulation signal can drive the modulation panel.

The visualization system 910 can include one or more beam combiners 928 (also known as beam splitters 928), which can combine light beams of different colors to form a single multi-color beam. For configurations in which the light sources 922 can include multiple light-emitting diodes of different colors, the visualization system 910 can include one or more wavelength-sensitive (e.g., dichroic) beam splitters 928 that can combine the light of different colors to form a single multi-color beam.

The visualization system 910 can direct the modulated light toward the eyes of the viewer in one of at least two configurations. In a first configuration, the visualization system 910 can function as a projector, and can include suitable projection optics 930 that can project the modulated light onto one or more screens 932. The screens 932 can be located a suitable distance from an eye of the user. The visualization system 910 can optionally include one or more lenses 934 that can locate a virtual image of a screen 932 at a suitable distance from the eye, such as a close-focus distance, such as 500 mm, 750 mm, or another suitable distance. In some examples, the visualization system 910 can include a single screen 932, such that the modulated light can be directed toward both eyes of the user. In some examples, the visualization system 910 can include two screens 932, such that the modulated light from each screen 932 can be directed toward a respective eye of the user. In some examples, the visualization system 910 can include more than two screens 932. In a second configuration, the visualization system 910 can direct the modulated light directly into one or both eyes of a viewer. For example, the projection optics 930 can form an image on a retina of an eye of the user, or an image on each retina of the two eyes of the user.

For some configurations of AR systems, the visualization system 910 can include at least a partially transparent display, such that a user can view the user’s surroundings through the display. For such configurations, the AR system can produce modulated light that corresponds to the augmentation of the surroundings, rather than the surroundings itself For example, in the example of a retailer showing a chair, the AR system can direct modulated light, corresponding to the chair but not the rest of the room, toward a screen or toward an eye of a user.

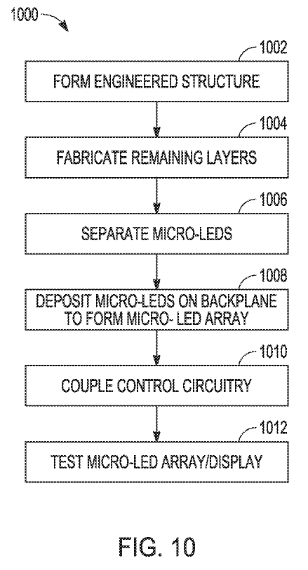

FIG. 10 illustrates an example method of fabricating a micro-LED array, according to some embodiments. Not all of the operations may be undertaken in the method 1000 of FIG. 10, and/or additional operations may be present. The method 1000 is separated into stages that may be undertaken by different entities. Further, not all of the operations need to be performed in the order shown by FIG. 10.

At operation 1002, the engineered structure is formed. As above, the engineered structure is formed to adjust directionality of the ambient light to another direction. In some embodiments, this formation may include roughening the bottom metal mirror of the microLED or patterning and/or roughening the top semiconductor surface (e.g., GaN) via electrochemical etching (e.g., oxalic acid). The roughness may be random and have feature dimensions of about 1-2 µm Note that the contact edges of the structure may be protected to permit adequate metallic contact to the semiconductor substrate. In other embodiments, the active region of the semiconductor may be grown on a patterned sapphire to provide a periodic structure into which voids or low refractive index particles may be introduced. In some embodiments, these voids or low refractive index particles may be introduced to the top layer of the semiconductor structure or within the active region and may be optimized to increase scattering. For example, the voids or low refractive index particles may have nanoscale or microscale features.

The remaining layers of the microLED structure are then fabricated at operation 1004. This may include the various layers described above and show, e.g, in FIG. 3B. In some embodiments, the remaining layers may include the layers of the multilayer semiconductor stack, after whose fabrication the wafer may be moved a different location to form a multilayer reflective structure at operation 1004 or to deposit a metallic mirror. To form the multilayer reflective structure, each layer may be sequentially deposited (including the DBR layers to form a DBR structure having a specific reflective center) using, for example, deposition processes tailored for the individual layers, a via is formed the layer structure using photolithographic processes, and the eVia deposited in the via before stripping the photoresist

An anti-reflective (AFR) coating may be formed on the semiconductor surface to avoid Fresnel reflection. The AFR coating may be, for example, 4-6 pairs of high/low index material tuned for normal incidence, about 0.5 µm. Glass or some other optically transparent material may then be deposited on the structure before or separation. For example, a pressure sensitive optically transparent material layer may be deposited and then pressure applied to conform to the material to the microLED shape.

The microLEDs of the wafer are then separated at operation 1006 and different microLEDs are combined into a microLED array at operation 1008. The different microLEDs are from different wafers and configured to emit at different visible wavelengths. The different visible wavelengths may be within a particular color or in different colors, dependent on the desired emission characteristics of the microLED array/display.

Control circuitry is then coupled to the microLED array at operation 1010. The control circuitry is used to control the individual microLEDs of the microLED array.

The microLED array/display may be tested at operation 1012. The testing may use the control circuitry to determine the emission characteristics of the microLED array/display.

Accordingly, different techniques may be used at one or more interfaces to adjust scattering or reflectance. These techniques include one or more of roughening the glass-air interface, roughening of the n-GaN surface (e.g., in a thin-film flip chip structure), deposition of silica nanospheres in an etched n-GaN surface, deposition of self-assembled periodic Si nanospheres on a sapphire substrate surface, deposition of a monolayer or more of Si hollow nanospheres on an (etched) n-GaN surface or a sapphire surface, patterning a sapphire substrate or a GaN surface using nanopatterns, plating AlN on a patterned sapphire substrate, and growth of a nanoporous InGaP/GaN DBR, for example. Such structures may permit adjustment of a controlled alteration from specular direction or otherwise deflect impinging ambient light into a range of angles to trap the ambient light inside the display to be absorbed by the absorbing backplane or outside the typical viewing angle of a user. The various embodiments may provide different types of scattering, including diffuse (random) scattering, beam deflection (e.g., diffraction), and/or refraction.

### EXAMPLES

Example 1 is a micro-light-emitting diode (micro-LED) structure comprising: a micro-LED comprising doped epitaxial semiconductor layers and an active region disposed between the doped epitaxial semiconductor layers, the active region configured to emit light at a predetermined wavelength; and an optically-transparent medium covering the micro-LED, at least one of the micro-LED and the optically-transparent medium having a structure configured to adjust a direction of ambient light of visible wavelengths that has entered the optically-transparent medium.

In Example 2, the subject matter of Example 1 includes, wherein the structure comprises nanospheres disposed in etched recesses of one of the doped epitaxial semiconductor layers.

In Example 3, the subject matter of Example 2 includes, wherein the nanospheres are silica nanospheres that are disposed in etched recesses of an n-doped GaN surface.

In Example 4, the subject matter of Examples 1-3 includes, wherein the structure comprises hollow nanospheres disposed on a layer between the optically-transparent medium and one of the doped epitaxial semiconductor layers opposing the optically-transparent medium.

In Example 5, the subject matter of Example 4 includes, wherein the hollow nanospheres are Si hollow nanospheres disposed in a monolayer.

In Example 6, the subject matter of Examples 1-5 includes, wherein the structure comprises a roughened layer of the optically-transparent medium, the roughened layer having at least one structure selected from structure including periodic structures, corrugated structures, and random structures.

In Example 7, the subject matter of Examples 1-6 includes, wherein the structure comprises self-assembled periodic nanospheres disposed in a layer on one of the doped epitaxial semiconductor layers.

In Example 8, the subject matter of Examples 1-7 includes, wherein the structure comprises etched recesses of one of the doped epitaxial semiconductor layers opposing the optically-transparent medium.

In Example 9, the subject matter of Example 8 includes, wherein the one of the doped epitaxial semiconductor layers is n-doped GaN, and the micro-LED is a thin-film flip chip structure.

In Example 10, the subject matter of Examples 1-9 includes, wherein the structure comprises plated AlN on a patterned sapphire substrate of the micro-LED.

In Example 11, the subject matter of Examples 1-10 includes, wherein the structure comprises a distributed Bragg reflector (DBR) adjacent to a top or bottom surface of the micro-LED, the DBR comprising a plurality of nanoporous layers.

In Example 12, the subject matter of Examples 1-11 includes, wherein the structure comprises a photolithographic structured surface.

In Example 13, the subject matter of Examples 1-12 includes, wherein the structure comprises an engineered surface that creates a controlled alteration of direction of the ambient light from a specular direction.

In Example 14, the subject matter of Example 13 includes, wherein the engineered surface is configured to deflect the ambient light into a range of angles to trap the ambient light inside the micro-LED structure to be absorbed by an absorbing backplane under the micro-LED.

In Example 15, the subject matter of Examples 13-14 includes, wherein the engineered surface is configured to deflect the ambient light into a range of angles that is outside a typical viewing angle of a user viewing the micro-LED structure.

In Example 16, the subject matter of Examples 1-15 includes, wherein the structure is configured to provide scattering of the ambient light, including at least one of diffuse scattering, beam deflection, or refraction.

Example 17 is a micro-light-emitting diode (micro-LED) system comprising: a plurality of micro-LEDs configured to emit light of different wavelength ranges, each micro-LED comprising: a micro-LED comprising doped epitaxial semiconductor layers and an active region disposed between the doped epitaxial semiconductor layers, the active region configured to emit light at a predetermined wavelength; and an optically-transparent medium covering the micro-LED, at least one of the micro-LED or the optically-transparent medium having a structure configured to alter a direction of ambient light of visible wavelengths that has entered the optically-transparent medium; and control circuitry configured to individually drive each of the micro-LEDs.

In Example 18, the subject matter of Example 17 includes, wherein the structure comprises at least one of: first nanospheres disposed in etched recesses of one of the doped epitaxial semiconductor layers, and second nanospheres disposed on a layer between the optically-transparent medium and the one of the doped epitaxial semiconductor layers opposing the optically-transparent medium.

In Example 19, the subject matter of Examples 17-18 includes, wherein the structure comprises etched recesses of one of the doped epitaxial semiconductor layers opposing the optically-transparent medium.

In Example 20, the subject matter of Examples 17-19 includes, wherein the structure comprises a distributed Bragg reflector (DBR) adjacent to a top or bottom surface of the micro-LED, the DBR comprising a plurality of nanoporous layers.

Example 21 is a method of fabricating a micro-light-emitting diode (LED) array including a plurality of micro-LEDs, the method comprising, for each micro-LED: fabricating a micro-LED comprising doped epitaxial semiconductor layers and an active region disposed between the doped epitaxial semiconductor layers, the active region configured to emit light at a predetermined wavelength; and encapsulating the micro-LED in optically-transparent medium covering the micro-LED, the micro-LED having a structure configured to alter a direction of ambient light of visible wavelengths that has entered the optically-transparent medium.

In Example 22, the subject matter of Example 21 includes, wherein fabricating the micro-LED comprises forming the structure by at least one of: etching one of the doped epitaxial semiconductor layers and depositing first nanospheres in recesses formed by the etching, and depositing second nanospheres on a layer between the optically-transparent medium and the one of the doped epitaxial semiconductor layers opposing the optically-transparent medium.

In Example 23, the subject matter of Examples 21-22 includes, wherein fabricating the micro-LED comprises forming the structure by at least one of: etching recesses of one of the doped epitaxial semiconductor layers opposing the optically-transparent medium, and nanopatterning a sapphire substrate, growing the micro-LED on the sapphire substrate, and removing the sapphire substrate.

In Example 24, the subject matter of Examples 21-23 includes, wherein fabricating the micro-LED comprises forming the structure by growing a distributed Bragg reflector (DBR) adjacent to at least one of a top surface and a bottom surface of the micro-LED, the DBR comprising a plurality of nanoporous layers.

In Example 25, the subject matter of Examples 21-24 includes, wherein fabricating the micro-LED comprises forming the structure by forming an engineered surface that creates a controlled alteration of direction of the ambient light from a specular direction.

Example 26 is at least one machine-readable medium including instructions that, when executed by processing circuitry, cause the processing circuitry to perform operations to implement of any of Examples 1-25

Example 27 is an apparatus comprising means to implement of any of Examples 1-25.

Example 28 is a system to implement of any of Examples 1-25.

Example 29 is a method to implement of any of Examples 1-25.

In the detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function.

The description uses the phrases “in an embodiment” or “in embodiments,” which may each refer to one or more of the same or different embodiments. Furthermore, the terms “comprising,” “including,” “having,” and the like, as used with respect to embodiments, are synonymous The disclosure may use perspective-based descriptions such as “above,” “below,” “top,” “bottom,” and “side”; such descriptions are used to facilitate the discussion and are not intended to restrict the application of disclosed embodiments. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the detailed description, reference is made to the accompanying drawings that form a part hereof, showing, by way of illustration, some of the embodiments that may be practiced. In the drawings, same reference numerals refer to the same or analogous elements/materials so that, unless stated otherwise, explanations of an element/material with a given reference numeral provided in context of one of the drawings are applicable to other drawings where elements/materials with the same reference numerals may be illustrated The accompanying drawings are not necessarily drawn to scale. Moreover, it will be understood that certain embodiments can include more elements than illustrated in a drawing, certain embodiments can include a subset of the elements illustrated in a drawing, and certain embodiments can incorporate any suitable combination of features from two or more drawings.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

In some examples provided herein, interaction may be described in terms of two, three, four, or more electrical components. However, this has been done for purposes of clarity and example only. It should be appreciated that the devices and systems described herein can be consolidated in any suitable manner. Along similar design alternatives, any of the illustrated components, modules, and elements of the accompanying drawings may be combined in various possible configurations, all of which are clearly within the broad scope. In certain cases, it may be easier to describe one or more of the functionalities of a given set of flows by only referencing a limited number of electrical elements.

As used herein, the states of switches may be referred to as “open” and “closed.” In some embodiments, a switch may comprise a physical throw, where the term “open” may refer to the throw opening the circuit in which the switch is implemented preventing the flow of current and the term “closed” may refer to the throw completing the circuit in which the switch is implemented allowing the flow of current. In some embodiments, a switch may comprise a transistor, where the term “open” may refer to the transistor presenting a high resistance that allows a minimal amount of current to flow and the term “closed” may refer to the transistor presenting that allows a large amount of current to flow. Further, when referring to a switch comprising a transistor allowing current flow or preventing current flow, it should be understood that current flow when the switch is allowing current flow may be an amount of current flow through the transistor when “closed” and the current flow when the switch is preventing current flow may be an amount of current flow through the transistor when “open” (which may be non-zero in some instances). It should be understood that the amount of current allowed to the flow through the transistor when “open” and when “closed” can be dependent on the characteristics of the transistor, and the terms “open” and “closed” are to be interpreted as one having ordinary skill in the art would understand when referring to a transistor being utilized as a switch.

It is to be understood that not necessarily all objects or advantages may be achieved in accordance with any particular embodiment described herein. Thus, for example, those skilled in the art will recognize that certain embodiments may be configured to operate in a manner that achieves or optimizes one advantage or group of advantages as taught herein without necessarily achieving other objects or advantages as may be taught or suggested herein.

It should be appreciated that the electrical circuits of the accompanying drawings and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

In some embodiments, any number of electrical circuits of the accompanying drawings may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), computer-readable non-transitory memory elements, etc. can be suitably coupled to the board based on a particular configuration, processing demands, computer designs, etc. Other components such as external storage, additional sensors, controllers for audio/video display, and peripheral devices may be attached to the board as plug-in cards, via cables, or integrated into the board itself. In various embodiments, the functionalities described herein may be implemented in emulation form as software or firmware running within one or more configurable (e.g., programmable) elements arranged in a structure that supports these functions. The software or firmware providing the emulation may be provided on non-transitory computer-readable storage medium comprising instructions to allow a processor to carry out those functionalities.

In some embodiments, the electrical circuits of the accompanying drawings may be implemented as stand-alone modules (e.g., a device with associated components and circuitry configured to perform a specific application or function) or implemented as plug-in modules into application specific hardware of electronic devices. Note that some embodiments may be readily included in a system on chip (SOC) package, either in part, or in whole. An SOC represents an integrated circuit (IC) that integrates components of a computer or other electronic system into a single chip. It may contain digital, analog, mixed-signal, and often radio frequency functions: all of which may be provided on a single chip substrate. Other embodiments may include a multi-chip-module (MCM), with a plurality of separate ICs located within a single electronic package and configured to interact closely with each other through the electronic package. In various other embodiments, components and/or procedures described herein may be implemented in one or more silicon cores in Application Specific Integrated Circuits (ASICs), Field Programmable Gate Arrays (FPGAs), and other semiconductor chips.

Note that the functions related to components and/or procedures described herein and/or the procedure may illustrate some of the possible functions that may be executed by, or within, the systems described herein. Some of these operations may be deleted or removed where appropriate, or these operations may be modified or changed considerably without departing from the scope. In addition, the timing of these operations may be altered considerably. The preceding operational flows have been offered for purposes of example and discussion. Substantial flexibility is provided by embodiments described herein in that any suitable arrangements, chronologies, configurations, and timing mechanisms may be provided without departing from the teachings.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. Note that all optional features of any of the devices and systems described herein may also be implemented with respect to the methods or processes described herein and specifics in the examples may be used anywhere in one or more embodiments.

1. A micro-light-emitting diode (micro-LED) structure comprising:
a micro-LED comprising doped epitaxial semiconductor layers and an active region disposed between the doped epitaxial semiconductor layers, the active region configured to emit light at a predetermined wavelength; and
an optically-transparent medium covering the micro-LED, at least one of the micro-LED and the optically-transparent medium having a structure configured to adjust a direction of ambient light of visible wavelengths that has entered the optically-transparent medium.

2. The micro-LED structure of claim 1, wherein the structure comprises nanospheres disposed in etched recesses of one of the doped epitaxial semiconductor layers.

3. The micro-LED structure of claim 2, wherein the nanospheres are silica nanospheres that are disposed in etched recesses of an n-doped GaN surface.

4. The micro-LED structure of claim 1, wherein the structure comprises hollow nanospheres disposed on a layer between the optically-transparent medium and one of the doped epitaxial semiconductor layers opposing the optically-transparent medium.

5. The micro-LED structure of claim 4, wherein the hollow nanospheres are Si hollow nanospheres disposed in a monolayer.

6. The micro-LED structure of claim 1, wherein the structure comprises a roughened layer of the optically-transparent medium, the roughened layer having at least one structure selected from structure including periodic structures, corrugated structures, and random structures.

7. The micro-LED structure of claim 1, wherein the structure comprises self-assembled periodic nanospheres disposed in a layer on one of the doped epitaxial semiconductor layers.

8. The micro-LED structure of claim 1, wherein the structure comprises etched recesses of one of the doped epitaxial semiconductor layers opposing the optically-transparent medium.

9. The micro-LED structure of claim 8, wherein the one of the doped epitaxial semiconductor layers is n-doped GaN, and the micro-LED is a thin-film flip chip structure.

10. The micro-LED structure of claim 1, wherein the structure comprises plated AlN on a patterned sapphire substrate of the micro-LED.

11. The micro-LED structure of claim 1, wherein the structure comprises a distributed Bragg reflector (DBR) adjacent to a top or bottom surface of the micro-LED, the DBR comprising a plurality of nanoporous layers.

12. The micro-LED structure of claim 1, wherein the structure comprises a photolithographic structured surface.

13. The micro-LED structure of claim 1, wherein:
the structure comprises an engineered surface that creates a controlled alteration of direction of the ambient light from a specular direction, and
the engineered surface is configured to deflect the ambient light into a range of angles at least one of:
to trap the ambient light inside the micro-LED structure to be absorbed by an absorbing backplane under the micro-LED, or
that is outside a typical viewing angle of a user viewing the micro-LED structure.

14. A micro-light-emitting diode (micro-LED) system comprising:
a plurality of micro-LEDs configured to emit light of different wavelength ranges, each micro-LED comprising:
a micro-LED comprising doped epitaxial semiconductor layers and an active region disposed between the doped epitaxial semiconductor layers, the active region configured to emit light at a predetermined wavelength; and
an optically-transparent medium covering the micro-LED, at least one of the micro-LED or the optically-transparent medium having a structure configured to alter a direction of ambient light of visible wavelengths that has entered the optically-transparent medium; and
control circuitry configured to individually drive each of the micro-LEDs.

15. The micro-LED system of claim 14, wherein the structure comprises at least one of:
first nanospheres disposed in etched recesses of one of the doped epitaxial semiconductor layers, and
second nanospheres disposed on a layer between the optically-transparent medium and the one of the doped epitaxial semiconductor layers opposing the optically-transparent medium.

16. The micro-LED system of claim 14, wherein the structure comprises at least one of:
etched recesses of one of the doped epitaxial semiconductor layers opposing the optically-transparent medium, or
a distributed Bragg reflector (DBR) adjacent to a top or bottom surface of the micro-LED, the DBR comprising a plurality of nanoporous layers.

17. A method of fabricating a micro-light-emitting diode (LED) array including a plurality of micro-LEDs, the method comprising, for each micro-LED:
fabricating a micro-LED comprising doped epitaxial semiconductor layers and an active region disposed between the doped epitaxial semiconductor layers, the active region configured to emit light at a predetermined wavelength; and
encapsulating the micro-LED in optically-transparent medium covering the micro-LED, the micro-LED having a structure configured to alter a direction of ambient light of visible wavelengths that has entered the optically-transparent medium.

18. The method of claim 17, wherein fabricating the micro-LED comprises forming the structure by at least one of:
etching one of the doped epitaxial semiconductor layers and depositing first nanospheres in recesses formed by the etching, and
depositing second nanospheres on a layer between the optically-transparent medium and the one of the doped epitaxial semiconductor layers opposing the optically-transparent medium.

19. The method of claim 17, wherein fabricating the micro-LED comprises forming the structure by at least one of:
etching recesses of one of the doped epitaxial semiconductor layers opposing the optically-transparent medium, and
nanopatterning a sapphire substrate, growing the micro-LED on the sapphire substrate, and removing the sapphire substrate.

20. The method of claim 17, wherein fabricating the micro-LED comprises forming the structure by at least one of:
growing a distributed Bragg reflector (DBR) adjacent to at least one of a top surface and a bottom surface of the micro-LED, the DBR comprising a plurality of nanoporous layers, or
forming an engineered surface that creates a controlled alteration of direction of the ambient light from a specular direction.
